(19) United States
(12) Patent Application Publication
(10) Pub. No.: US 2009/0000552 A1
(43) Pub. Date: Jan. 1, 2009

(54) SUBSTRATE HOLDER AND VACUUM FILM DEPOSITION APPARATUS

(76) Inventor: Hiroshi SOHDA, Kanagawa (JP)

Correspondence Address: BIRCH STEWART KOLASCH & BIRCH, PO BOX 747, FALLS CHURCH, VA, 22040-0747, US

(21) Appl. No.: 12/145,897

(22) Filed: Jun. 25, 2008

(30) Foreign Application Priority Data
Jun. 29, 2007 (JP) 2007-173230

(51) Int. Cl. C23C 16/00

(52) U.S. Cl. 118/728

(57) ABSTRACT

A vacuum film deposition apparatus in which a film is formed on a substrate by a vacuum film deposition process includes a holder which has a substrate supporting surface which is in a curved shape and is brought into contact with the substrate. A substrate holder for holding the substrate includes a base having the substrate supporting surface. The apparatus and the substrate holder further include a contact detection mechanism which detects a state of contact between the substrate and the substrate supporting surface, a load applying mechanism which is provided outside the substrate supporting surface and supports the substrate by applying a load to end faces of the substrate and a control unit which controls the load the load applying mechanism applies to the substrate based on output from the contact detection mechanism.

The entire contents of a document cited in this specification are incorporated herein by reference.

### BACKGROUND OF THE INVENTION

The present invention relates to a substrate holder for holding a substrate and a vacuum film deposition apparatus used in forming a film on the substrate held on the substrate holder by a vacuum film deposition method.

A radiation image detector which records a radiation image by first allowing a radiation (e.g. X-rays, α-rays, β-rays, γ-rays, electron beams or uv rays) to pass through an object, then picking up the radiation as an electric signal has conventionally been used in such applications as medical diagnostic imaging and industrial nondestructive testing.

Examples of this radiation image detector include a solid-state radiation detector (so-called “flat panel detector” which is hereinafter abbreviated as “FPD”) that picks up the radiation as an electric image signal, and an X-ray image intensifier that picks up the radiation image as a visible image.

FPDs are operated by one of two methods, direct conversion method and indirect conversion method; in the direct method which involves the use of a film of photoconductive material such as amorphous selenium and a thin film transistor (TFT), electron hole pairs (e-h pairs) emitted from the photoconductive film upon incidence of radiation are collected and the collected e-h pairs are read as an electric signal by the TFT, whereby the radiation is “directly” converted to the electric signal; in the indirect conversion method, a phosphor layer (scintillator layer) which is formed of a phosphor that emits light (fluorescence) upon incidence of radiation is provided such that it converts the radiation to visible light, which is read with a photoelectric transducer, whereby the radiation “as visible light” is converted to an electric signal.

An exemplary apparatus for forming a phosphor layer or a film of photoconductive material such as amorphous selenium on a substrate includes a vacuum evaporation apparatus that forms a vapor-deposited film on a substrate by evaporating an evaporable material in a vacuum chamber evacuated to a predetermined pressure.

In such vacuum evaporation apparatus, an evaporable material within an evaporation source is evaporated, moved upward in the form of vapors and vapor-deposited on a substrate to form a film thereon, so the substrate is disposed on the upper side in the vertical direction of the evaporation source. Thereforer in such evaporation apparatus, a substrate holder holds the substrate with its surface on which an evaporable material is to be deposited open to the lower side in the vertical direction.

An illustrative substrate holder for holding a substrate is a substrate holder (substrate holding apparatus) disclosed in JP 10-147865 A which includes a base having a substrate supporting surface which is concave and forms a part of a cylindrical shape and a plurality of elastic members which press inward uncurved end faces in two sides of the substrate disposed on the substrate supporting surface of the base along the substrate supporting surface.

### SUMMARY OF THE INVENTION

In the substrate holder such as the one described in JP 10-147865 A, a substrate is curved and its end faces are pressed inward, enabling the substrate to be brought into close contact with and held on the substrate supporting surface. In addition, any thermal expansion of the substrate can be absorbed, thus preventing defects such as deformation and cracking from occurring in the substrate.

In the substrate holder described in JP 10-147865 A, however, the substrate which is in close contact with the substrate holder when mounted thereon may be gradually separated or displaced from the substrate holder during the film formation on the substrate, causing non-uniformity in the vapor-deposited film formed on the substrate. Particularly in the case where the substrate temperature is adjusted by heat from the substrate holder, the substrate temperature will become uneven to increase non-uniformity in the vapor-deposited film.

On the other hand, a large load preliminarily applied to the substrate to prevent such displacement of the substrate may cause buckling of the substrate. A vapor-deposited film formed on the substrate having been compressed by addition of a large load may also be nonuniform.

The present invention has been made to solve the aforementioned problems and it is an object of the present invention to provide a substrate holder which comes in close contact with a substrate and is capable of uniform transmission of heat to the substrate.

Another object of the present invention is to provide a vacuum film deposition apparatus which is capable of holding a substrate in the state in which the substrate is in close contact with a substrate holder and accurately adjusting the substrate temperature, thereby forming a high-quality film on the substrate.

In order to achieve the above objects, according to a first aspect of the present invention, there is provided a vacuum film deposition apparatus in which a film is formed on a substrate by a vacuum film deposition process, comprising:

a holder which has a substrate supporting surface which is in a curved shape and is brought into contact with the substrate;

a contact detection mechanism which detects a state of contact between the substrate and the substrate supporting surface;

a load applying mechanism which is provided outside the substrate supporting surface of the holder and supports the substrate by applying a load to end faces of the substrate; and

a control-unit which controls the load the load applying mechanism applies to the substrate based on output from the contact detection mechanism.

It is preferred that the contact detection mechanism have detection devices disposed at a plurality of points of the substrate supporting surface in the holder, and that the detection devices are used to detect the state of contact between the substrate and the substrate supporting surface of the holder at the plurality of points.

The detection devices are preferably displacement sensors which are provided at the substrate supporting surface of the holder contacting the substrate and detect a displacement of the substrate.

The detection devices are preferably temperature sensors which are provided at the substrate supporting surface of the holder contacting the substrate and detect a temperature of the substrate, the temperature sensors detecting the state of contact between the substrate and the substrate supporting surface of the holder based on changes in temperature.

The control unit preferably controls the load applied by the load applying mechanism to the substrate by changing stepwise the load to the substrate by a fixed amount.

The holder preferably has a thermally conductive sheet provided on the substrate supporting surface of the holder contacting the substrate.

Preferably, the load applying mechanism is provided outside both ends of the substrate supporting surface of the holder, supports the substrate by applying the load to the end faces of the substrate, and includes first actuators for applying a load to a first end face of the substrate and second actuators for applying a load to a second end face of the substrate which is opposite from the first end face.

Preferably, the vacuum film deposition apparatus further comprises a holder mounting mechanism which is used for attachment and detachment of the holder.

In order to achieve the above objects, according to a second aspect of the present invention, there is provided a substrate holder for holding a substrate on which a film is to be formed, comprising:

a base having a substrate supporting surface which is in a curved shape and is brought into contact with the substrate;

a contact detection mechanism which detects a state of contact between the substrate and the substrate supporting surface;

a load applying mechanism which is provided outside the substrate supporting surface of the base and supports the substrate by applying a load to end faces of the substrate; and

a control unit which controls the load the load applying mechanism applies to the substrate based on output from the contact detection mechanism.

It is preferred that the contact detection mechanism have detection devices disposed at a plurality of points of the substrate supporting surface, and that the detection devices are used to detect the state of contact between the substrate and the substrate supporting surface at the plurality of points.

The detection devices are preferably displacement sensors which are provided at the substrate supporting surface contacting the substrate and detect a displacement of the substrate.

The detection devices are preferably temperature sensors which are provided at the substrate supporting surface contacting the substrate and detect a temperature of the substrate, the temperature sensors detecting the state of contact between the substrate and the substrate supporting surface based on changes in temperature.

The control unit preferably controls the load applied by the load applying mechanism to the substrate by changing stepwise the load to the substrate by a fixed amount.

The holder preferably has a thermally conductive sheet provided on the substrate supporting surface contacting the substrate.

Preferably, the load applying mechanism is provided outside both ends of the substrate supporting surface, supports the substrate by applying the load to the end faces of the substrate, and includes one or more first actuators for applying a load to a first end face of the substrate and one or more second actuators for applying a load to a second end face of the substrate which is opposite from the first end face.

The control unit preferably causes the actuators to individually adjust the load to be applied to the substrate.

The load applying mechanism is also preferably a mechanism in which the load is applied to the first end face of the substrate while the second end face which is opposite from the first end face is fixed.

The substrate holder of the present invention can bring the substrate into close contact with the substrate supporting surface with an appropriate load applied to the substrate, thus enabling uniform transmission of heat to the substrate while preventing an excessive load from being applied thereto. The entire surface of the substrate can be thus kept uniform to form a uniform film.

The vacuum film deposition apparatus of the present invention can bring the substrate into close contact with the substrate supporting surface with an appropriate load applied to the substrate, so the substrate temperature can be accurately adjusted without applying an excessive load, thus enabling a uniform film to be formed on the substrate surface while preventing the substrate from being deformed.

### BRIEF DESCRIPTION OF THE DRAWINGS

FIG. 1A is a front view schematically showing the structure of a vacuum evaporation apparatus according to an embodiment of a vacuum film deposition apparatus of the present invention;

FIG. 1B is an enlarged front view showing in an enlarged scale a substrate holder and a support portion for supporting the substrate holder in the vacuum evaporation apparatus shown in FIG. 1A;

FIG. 2 is a front view schematically showing the structure of the substrate holder shown in FIGS. 1A and 1B;

FIG. 3 is a plan view of the substrate holder shown in FIG. 2;

FIG. 4A schematically shows the structure of a holder communicating portion and a base communicating portion that may be used in the vacuum evaporation apparatus shown in FIGS. 1A and 1B;

FIGS. 4B and 4C are partial cross-sectional views each schematically showing the structure of the junction between the holder communicating portion and the base communicating portion; and

FIG. 5 is a front view schematically showing the structure of another embodiment of the substrate holder of the present invention.

### DETAILED DESCRIPTION OF THE PREFERRED EMBODIMENTS

On the pages that follow, the substrate holder and the vacuum film deposition apparatus of the present invention are described in detail with reference to the preferred embodiments depicted in the accompanying drawings.

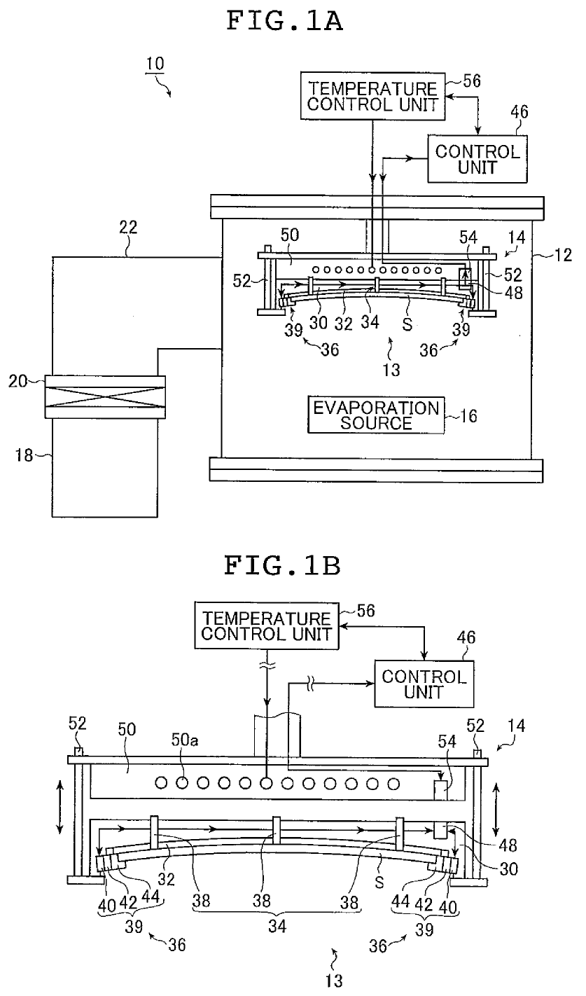

FIG. 1A is a front view schematically showing the structure of a vacuum evaporation apparatus 10 according to an embodiment of the vacuum film deposition apparatus of the present invention in which the substrate holder of the present invention is used. FIG. 1B is an enlarged front view showing in an enlarged scale a substrate holder 13, a holder mounting section 14 and their peripheries in the vacuum evaporation apparatus 10 shown in FIG. 1A. The substrate holder 13 and the holder mounting section 14 in the vacuum evaporation apparatus 10 are in close contact with each other in FIG. 1A but are not in FIG. 1B.

The vacuum evaporation apparatus 10 shown in FIG. 1A includes a vacuum chamber 12, the substrate holder 13, the holder mounting section 14, an evaporation source 16, a vacuum pump 18, a valve 20 and an evacuation line 22.

In the vacuum evaporation apparatus 10, the vacuum chamber 12 is evacuated to reduce the internal pressure and an evaporable material filled into the evaporation source 16 is heated to melt and evaporate to form a film of the evaporated material on the surface of a substrate S held by the holder mounting section 14.

In addition to the illustrated components, the vacuum evaporation apparatus 10 of the present invention may of course include various components of vacuum evaporation apparatuses or vacuum evaporation units, as exemplified by a gas introducing means for introducing various gases such as inert gases (e.g., argon) into the vacuum chamber 12, a shutter for blocking out vapors from the evaporation source 16, and a deposition preventing cover which guides the material evaporated from the evaporation source 16 to the substrate S to prevent deposition of the evaporated material to other areas than the substrate S.

There is no particular limitation on the substrate S used in the present invention, and use may be made of various materials appropriate to products to be obtained, as exemplified by a glass plate, a plastic (resin) film or plate, and a metal plate.

Any film may be deposited (formed) on the substrate S without any particular limitation, and films capable of being deposited by vacuum evaporation are all available.

As will be described later in detail, the vacuum film deposition apparatus of the present invention is capable of accurate measurement of the substrate temperature even in the case where the state of the substrate has changed during vapor deposition as exemplified by the change in its own weight, whereby a film can be formed on the substrate by vapor deposition at a constant temperature.

Therefore, the present invention is particularly suitable for formation of a thick film that requires vapor-depositing at a predetermined temperature for a certain period of time, and can be advantageously used in forming a photoconductive layer in a direct type radiation image detector (FPD), the photoconductive layer requiring a thickness of about 200 μm to about 1,000 μm. More particularly, an amorphous selenium film serving as the photoconductive layer of the FPD can be advantageously formed in a uniform manner under more constant temperature conditions, because selenium as the film-forming material evaporates at a low temperature.

In the case of using the vacuum film deposition apparatus of the present invention in manufacturing FPDs, the FPDs produced may be of an electric reading system which uses a film of photoconductive material such as amorphous selenium and a thin film transistor (TFT) and which involves collecting electron hole pairs (e-h pairs) emitted from the photoconductive film upon incidence of radiation and detecting them as an electric current from a portion where TFT switching was carried out to thereby obtain a radiation image, or of an optical reading system which includes a photoconductive layer for recording and a photoconductive layer for reading both formed of an amorphous selenium compound or the like and a charge accumulation layer of As₂Se₃ formed between these photoconductive layers and which involves accumulating latent image charges by irradiation with radiation, allowing the latent image charges to flow by irradiation with reading light and detecting them as an electric current to thereby obtain a radiation image.

The vacuum chamber 12 is a highly airtight vessel made of iron, stainless steel, aluminum, etc. Various vacuum chambers (e.g. bell jar and vacuum vessel) employed in apparatuses for vacuum evaporation may be used for the vacuum chamber 12. To the vacuum chamber 12 is connected the vacuum pump 18 via the evacuation line 22, which in turn is provided with the valve 20 which hermetically seals the evacuation line 22 and adjusts the amount of air discharged through the vacuum pump 18. Various valves such as a solenoid valve and a hydraulic valve may be used for the valve 20.

The vacuum pump 18 is used to evacuate the vacuum chamber 12 to a predetermined degree of vacuum.

Various types of vacuum pumps as used in vacuum evaporation apparatuses can be used for the vacuum pump 18 without any particular limitation as long as they help to attain the requisite vacuum level. For example, an oil diffusion pump, a cryogenic pump, a turbomolecular pump or any other pump may be used optionally in combination with a cryogenic coil.

A description is given below of the substrate holder 13.

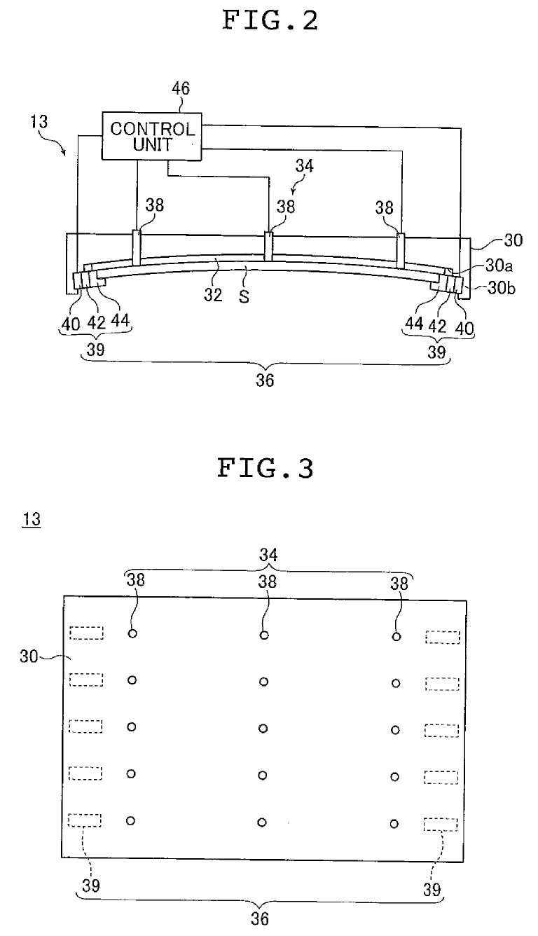

FIG. 2 is a front view schematically showing the structure of the substrate holder 13 of the present invention, and FIG. 3 is a plan view of the substrate holder 13 shown in FIG. 2.

The substrate holder 13 includes a base 30 which holds the substrate S, a thermally conductive sheet 32 which transmits heat from a temperature adjusting plate 50 (see FIGS. 1A and B) to be described later, a contact detection mechanism 34 which detects the state of contact with the substrate S, a load applying mechanism 36 which applies a load for fixing the substrate S to the base 30, and a control unit 46 which adjusts the load applied to the substrate S by the load applying mechanism 36, and holds the substrate S with its area where a film is to be vapor-deposited open. Although not shown in FIG. 2 in order to illustrate the relation between the contact detection mechanism 34 and the load applying mechanism 36 on one hand and the control unit 46 on the other, the substrate holder 13 has a holder communicating portion 48 which relays the information exchanged for transmission/reception between the contact detection mechanism 34 and the load applying mechanism 36, and the control unit 46. The holder mounting section 14 to be described later has a base communicating portion 54 connected to the control unit 46. In other words, the contact detection mechanism 34 (its temperature sensors 38) and the load applying mechanism 36 (its heaters 40) are connected to the control unit 46 through the holder communicating portion 48 and the base communicating portion 54.

The base 30 is in the shape of a plate whose region where the base 30 contacts the substrate S (more precisely via the thermally conductive sheet 32) is concave when seen from the cross section in a predetermined direction (horizontal direction in FIG. 1A), that is, a surface 30a of the base 30 contacting the substrate S (hereinafter referred to as a “substrate supporting surface” 30a) is curved such that the distance between the substrate supporting surface 30a and its opposite surface decreases from both ends toward the central portion. When seen in a direction perpendicular to the predetermined direction (direction perpendicular to the paper in FIG. 1A), the base 30 has a rectangular cross-sectional shape.

The base 30 has projections 30 which are provided at both ends in the curved direction of the substrate supporting surface 30a, that is, outside the region of contact between the substrate supporting surface 30a and the substrate S.

The thermally conductive sheet 32 is a sheet member made of a thermally conductive material and is provided on the substrate supporting surface 30a of the base 30. Heat from the base 30 can be transmitted to the substrate S uniformly with high efficiency by providing the thermally conductive sheet 32 between the base 30 and the substrate S.

Various thermally conductive sheets may be used for the thermally conductive sheet 32 and it is preferable to use sheets in which thermally conductive particles, thermally conductive fillers or the like are dispersed in resins such as silicone resins, acrylic resins and ethylene propylene resins.

The thermally conductive sheet 32 preferably has a non-adhesive layer on its surface facing the substrate S. Provision of the non-adhesive layer on the substrate S side facilitates attachment/detachment of the substrate S. It is further preferable to use a layer surface-treated by electron beam irradiation, a plastic film, or a coating layer of a non-adhesive resin for the non-adhesive layer or to perform powder processing on the surface of the thermally conductive sheet facing the substrate.

As shown in FIG. 3, the contact detection mechanism 34 has the temperature sensors 38 disposed in a matrix (i.e., in a two-dimensional manner) in the base 30.

A tip of the temperature sensor 38 projects from the substrate supporting surface 30a and the thermally conductive sheet 32 has a hole at a position corresponding to the temperature sensor 38.

The temperature sensor 38 is thus exposed at the surface where the substrate holder 13 contacts the substrate S and comes into contact with the substrate S which is in close contact with and held on the substrate supporting surface 30a thereby measuring the temperature of the substrate S held on the base 30 (more accurately, held via the thermally conductive sheet 32).

Various known sensors may be used for the temperature sensor, as exemplified by a thermocouple in which both ends of two metal wires of different kinds are joined together and the temperature is measured from the thermoelectromotive force generated due to a difference in temperature between the points of contact at both ends, and a resistance temperature sensor or thermistor for use in measuring temperature from resistance that varies with temperature.

The load applying mechanism 36 has a plurality of actuators 39 which are disposed at both projections 30b of the base 30 so as to be spaced apart from each other at predetermined intervals. In other words, the actuators are disposed in a row at each of the projections 30b.

The actuator 39 includes a heater 40 serving as a heating element or a heating mechanism, a thermally expandable member 42 formed of a material which is expanded or contracted by heat from the heater 40, and a fitting portion 44 which is made of a heat insulating material and has a projection for fitting the substrate S into the fitting portion while supporting the surface of the substrate S opposite from the substrate supporting surface 30a, and applies a load to the substrate S from the lateral surfaces of the substrate S in the direction along the substrate supporting surface 30a of the base 30.

The actuator 39 has the heater 40, the thermally expandable member 42 and the fitting portion 44 disposed in this order from the inner surface of the projection 30b toward the substrate S. In other words, the actuator 39 has the heater 40 secured to the projection 30b, the fitting portion 44 contacting the substrate S and the thermally expandable member 42 disposed between the heater 40 and the fitting portion 44.

The fitting portions 44 in the actuators 39 of the load applying mechanism 36 disposed at both the projections 30b, respectively, press the substrate S toward the substrate supporting surface 30a to secure the substrate S as it is in close contact with the substrate supporting surface 30a via the thermally conductive sheet 32. This state is hereinafter referred to simply as “with the substrate S in close contact with the substrate supporting surface 30a”. The substrate supporting surface 30a is concave as described above, so the substrate S is secured to the base 30 by pressing the ends of the substrate S in the direction along the substrate supporting surface 30a.

In addition, in the actuator 39, the heater 40 heats the thermally expandable member 42, which then expands to enable the fitting portion 44 to be moved.

The load applying mechanism 36 can adjust the load to be applied to the substrate S by adjusting the distance between the fitting portions 44 disposed at the opposed projections 30 through movements of the fitting portions 44 of the respective actuators 39.

In the embodiment under consideration, the heaters are used to heat the thermally expandable members 42, but heating/cooling mechanisms may be used instead of the heaters. Use of such heating/cooling mechanisms enables the thermally expandable members to be expanded or contracted to increase or decrease the load to be applied to the substrate S.

The control unit 46 is connected to the temperature sensors 38 of the contact detection mechanism 34 and the heaters 40 in the respective actuators 39 of the load applying mechanism 36.

The control unit 46 checks the state of contact between the substrate S and the substrate supporting surface 30a of the base 30 based on the temperature detected by each temperature sensor 38 and adjusts the amount of heating of the heater 40 in each actuator 39 based on the checking result to adjust the load to be applied to the substrate S.

For example, in the case where a decrease in temperature by a certain value or more per unit time is detected by a temperature sensor 38, it is determined that the substrate S is separated from the temperature sensor 38 and the heaters 40 of the actuators 39 at positions corresponding to the separation of the substrate S from the temperature sensor 38 are heated to move the fitting portions 44 and increase the load to be applied to the substrate S, whereby the substrate S is pressed on the substrate supporting surface 30a side.

In this way, the substrate S separated from the substrate supporting surface 30a is brought into close contact with the substrate supporting surface 30a of the base 30.

There is no particular limitation on the method of adjusting the load to be applied to the substrate S in the control unit 46. For example, use may be made of a method in which the amount of heat from the heater 40 to heat the thermally expandable member 42 is increased by a certain amount to change the load applied by the actuator 39 and each time the load is changed, it is checked whether the state of contact as detected by the contact detection mechanism 34 is desired or not, and the load to the substrate S is stepwise changed until a desired state of contact is achieved, and a method in which the load to be applied by the actuator 39 is changed based on the relation preliminarily established between the detection value from the contact detection mechanism 34, film thickness and load applied.

Although not shown in FIG. 3, the substrate holder 13 further includes the holder communicating portion 48.

The holder communicating portion 48 is disposed at an end of the base 30 and is connected to the temperature sensors 38 of the contact detection mechanism 34 and the heaters 40 in the respective actuators 39 of the load applying mechanism 36. The holder communicating portion 48 outputs temperature measurement signals detected by the contact detection mechanism 34 to the base communicating portion 54 to be described later.

The holder communicating portion 48 may output the temperature measurement signals (electric signals) from the contact detection mechanism 34 (more specifically its temperature sensors 38) to the base communicating portion 54 without any further processing or after conversion to digital signals.

The holder mounting section 14 includes the temperature adjusting plate 50 that heats and/or cools the substrate holder 13 and the substrate S, a support portion 52 that supports the substrate holder 13, and the base communicating portion 54 that receives the signals outputted from the holder communicating portion 48 of the substrate holder 13.

The temperature adjusting plate 50 is a plate member having a temperature adjusting mechanism 50a disposed therein and is provided on the upper surface within the vacuum chamber 12.

The temperature adjusting plate 50 heats or cools the substrate holder 13 to adjust the temperature of the substrate S.

A method of heating or cooling the temperature adjusting plate 50 by circulating a heating medium in piping provided within the temperature adjusting plate 50 and a method of heating or cooling the temperature adjusting plate 50 by controlling the current applied to a Peltier device provided within the temperature adjusting plate 50 are used for the temperature adjusting mechanism 50a. In the case where the temperature adjusting plate 50 is temperature-controlled only by heating, use may also be made of a method in which heating wires are arranged and heated.

The support portion 52 is disposed at the temperature adjusting plate 50 and has hooks for supporting the periphery of the substrate holder 13. The hooks in the support portion 52 are moved by an elevator mechanism in the vertical direction in FIG. 1A.

The support portion 52 moves the hooks for supporting the substrate S to the temperature adjusting plate 50 side (to the position shown in FIG. 1A) to support the edges of the substrate holder 13 from the surface of the substrate holder 13 on the evaporation source 16 side such that the base 30 of the substrate holder 13 (more specifically, the surface of the base 30 opposite from the surface supporting surface 30a) is brought into close contact with the temperature adjusting plate 50.

In the case where the substrate holder 13 after the end of vapor deposition is detached from the support portion 52, the support portion 52 is moved to the side of the evaporation source 16 (to the position shown in FIG. 1B) and the substrate holder 13 is released from the state in which the substrate holder 13 is in close contact with the temperature adjusting plate 50, then detached.

For the elevator mechanism, use may be made of a linear mechanism, a movement mechanism by means of a force applied by a spring, and a movement mechanism by means of a wire.

The base communicating portion 54 is disposed at the surface of the temperature adjusting plate 50 on the substrate holder 13 side. When the substrate holder 13 is supported, the base communicating portion 54 comes in contact with the holder communicating portion 48 of the substrate holder 13 to receive signals outputted from the holder communicating portion 48.

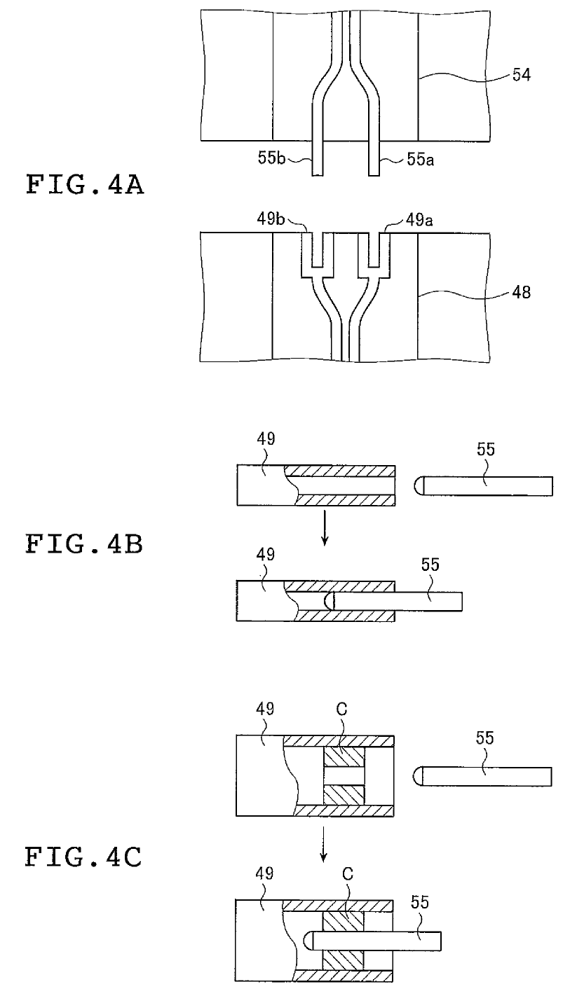

FIG. 4A schematically shows in an enlarged scale the holder communicating portion 48 and the base communicating portion 54. The holder communicating portion 48 has sockets 49 (first socket 49a and second socket 49b) electrically connected to the temperature sensors 38. On the other hand, the base communicating portion 54 has terminals 55 (first terminal 55a and second terminal 55b) which are connected to (electric) signal lines independent of each other and are inserted and fitted into the first and second sockets 49a and 49b, respectively. The present invention may be configured such that the holder communicating portion 48 has the terminals 55, whereas the base communicating portion 54 has the sockets 49.

When the support portion 52 elevates the substrate holder 13 (hooks) to bring the substrate holder 13 into close contact with the temperature adjusting plate 50 as described above, the terminals 55 are inserted and fitted into the sockets 49 to electrically connect the holder communicating portion 48 with the base communication portion 54.

There is no particular limitation on the shapes of the socket 49 and the terminal 55, and it is preferable to apply a configuration in which the terminal 55 in a rod shape (cylindrical shape) is inserted or press-fitted into the socket 49 in a cylindrical shape, as schematically shown in FIG. 4B. In an alternative configuration, the terminal 55 in a rod shape is press-fitted into the socket 49 in a cylindrical shape such that the terminal 55 can he press-fitted into a conductive member C provided within the socket 49.

In order to perform accurate temperature measurement, it is important to prevent contact electric resistance between the holder communicating portion 48 and the base communication portion 54 (at the connector portion therebetween). The above configuration improves the contact force between the holder communicating portion 48 and the base communicating portion 54 and therefore the contact area to enable a signal to be more consistently outputted from the holder communicating portion 48 to the base communicating portion 54.

The evaporation source 16 is provided on the lower side in the vertical direction than the holder mounting section 14 so as to face the holder mounting section 14 within the vacuum chamber 12. The evaporation source 16 heats to melt the evaporable material, then evaporates it toward the substrate S.

As the evaporation source 16, use may be made of, for example, an evaporation source which includes a crucible accommodating (containing) the evaporable material and a heating source for heating the crucible and therefore the evaporable material filled thereinto and in which the evaporable material is heated to evaporate by resistance heating of the crucible from the heating source.

The evaporation source is not limited to the one having the above-mentioned structure, and various types of crucibles including so-called boat-type crucibles and cylindrical or cup-type crucibles that open at their upper ends are all available.

The heating mechanism for the evaporation source is not limited to a heating mechanism in which an electric current is applied to the crucible for resistance heating to heat the crucible. Various heating mechanisms that may be used in vacuum evaporation are all available as long as induction heating and electron beam (EB) heating can be used in accordance with the film-forming conditions such as the degree of vacuum upon vapor deposition.

The evaporation source may be provided with a temperature measuring means for measuring the temperature of the evaporable material (or the crucible). An example of the temperature measuring means that may be used includes a thermocouple.

The temperature is measured by the temperature measuring means and the amount of heating in the evaporation source is adjusted based on the measurement results, enabling the temperature of the evaporable material to be kept constant, thus leading to consistent evaporation of the evaporable material.

The vacuum evaporation apparatus 10 of the embodiment under consideration uses a single evaporation source 16, but this is not the sole case of the present invention. The vacuum evaporation apparatus 10 may have a plurality of evaporation sources 16 disposed therein or may perform multi-source vacuum evaporation with a plurality of evaporation sources 16 containing different evaporable materials.

A temperature control unit 56 controls the amount of heating or cooling in the temperature adjusting mechanism 50a based on the temperature measurements of the substrate S transmitted from the control unit 46 to adjust the temperature of the substrate S to a desired value.

The substrate holder and the vacuum film deposition apparatus of the present invention are described below in greater detail with reference to the operation of the vacuum evaporation apparatus 10 shown in FIGS. 1A and 1B.

First, the substrate S is accommodated into the substrate holder 13.

Then, the evaporation source 16 is charged with a predetermined amount of evaporable material and the substrate holder 13 containing the substrate S is mounted on the holder mounting section 14 at its predetermined position. More specifically, the substrate holder 13 is secured with the hooks to the holder mounting section 14 to bring the base 30 into close contact with the temperature adjusting plate 50 and connect the base communicating portion 54 with the holder communicating portion 48.

Then, the vacuum chamber 12 is closed and evacuated by the vacuum pump 18 to a predetermined degree of vacuum.

The vacuum pump 18 is used to evacuate the system (i.e., the vacuum chamber 12) to a high degree of vacuum. Further, it is preferable to introduce argon gas into the system through a gas introducing means to achieve a degree of vacuum between about 0.01 Pa and 3 Pa (which is hereinafter referred to as medium vacuum for the sake of convenience).

When the vacuum chamber 12 has reached a predetermined degree of vacuum, an electric current is applied to the evaporation source 16 to start heating the evaporable material.

At the point in time when the evaporable material (and/or the crucible) has reached a predetermined temperature, formation of a film on the substrate S by vapor deposition is started.

When the film is vapor-deposited on the substrate S, the temperature sensors 38 of the contact detection mechanism 34 measure the temperature of the substrate S. The measurement data is sent to the holder communicating portion 48, then to the base communicating portion 54 to be received by the control unit 46.

Based on the measurements from the temperature sensors 38 of the contact detection mechanism 34, the control unit 46 checks the state of contact between the substrate supporting surface 30a of the base 30 in the substrate holder 13 and the substrate S through the thermally conductive sheet 32. Based on the checking result, the load applying mechanism 36 adjusts the load to be applied to the substrate S. More specifically, when it is detected that the substrate S is separated from (is not in close contact with) the substrate supporting surface 30a, the corresponding heaters 40 of the load applying mechanism 36 are actuated to heat the thermally expandable members 42 to increase the load to be applied to the substrate S, whereby the substrate S is brought into close contact with the substrate supporting surface 30a.

In addition, the temperature control unit 56 adjusts the amount of heating or cooling in the temperature adjusting plate 50 based on the temperature measurement data of the substrate S calculated in the control unit 46 from the measurements obtained in the contact detection mechanism 34.

A film is thus vapor-deposited on the substrate S while adjusting the load to be applied to the substrate S and the amount of heating or cooling in the temperature adjusting plate 50.

When the vapor-deposited film with a predetermined thickness has been formed, heating of the evaporation source 16 is stopped. The vacuum chamber 12 is restored to atmospheric pressure and opened, and the substrate S having the film vapor-deposited thereon is taken out from the vacuum chamber 12.

The thickness of the vapor-deposited film (film thickness) may be controlled by the film deposition rate corresponding to the predetermined heating conditions or based on the film thickness directly measured with a displacement gauge or other instrument. Alternatively, the film thickness may be controlled with a meter for measuring the quantity of evaporation using a crystal oscillator or the like.

In this way, the vacuum evaporation apparatus 10 uses the evaporable material to vapor-deposit a film on the substrate S.

In the present invention, the load applying mechanism 36 adjusts the load to be applied to the substrate S based on the detection results from the contact detection mechanism 34 to enable an appropriate load to be added to the substrate S according to the weight of the substrate even in the case where its weight has changed after deposition of the evaporated material, thus making it possible to bring the substrate S into close contact with the substrate supporting surface 30a of the substrate holder 13. In other words, insufficient contact between the substrate S and the substrate holder 13 can be prevented. Further, even in the case of a large-sized substrate, the substrate can be held in a stable manner without any deformation by holding the substrate in a curved state along the substrate supporting surface 30a.

By adjusting the load to be applied through detection of the state of contact between the substrate S and the substrate holder 13, the substrate S can be held with an appropriate load, thus preventing the substrate S from deforming due to an excessive load applied.

By thus applying an appropriate load to the substrate S to bring it into close contact with the substrate holder 13, heat can be consistently transmitted from the substrate holder to the substrate S to make the in-plane temperature of the substrate S uniform thereby vapor-depositing a high-quality film on the substrate.

Measurement of the substrate temperature with the temperature sensors of the contact detection mechanism disposed in the substrate holder for holding the substrate enables the state of contact between the substrate and the measurement portions or the positions where they are in contact with each other to be made constant, thus measuring the substrate temperature under constant conditions. In other words, the substrate temperature can be accurately measured.

Irrespective of the state of contact between the holder communicating portion and the base communicating portion, the measurements can be taken out from the substrate holder in the form of electric signals, whereby the measurement data obtained can be sent to the control unit without any further processing even with the substrate holder of a detachable structure, thus enabling the state of contact of the substrate with the substrate holder and the temperature to be detected without any variation.

The measurements can be obtained under the constant conditions to adjust the substrate temperature in a consistent manner, thus enabling a uniform high-quality film to be vapor-deposited on the substrate.

In this way, a uniform high-quality film can be formed on the substrate by vapor deposition even in the case of vapor-depositing a thick film at a low temperature.

The substrate temperature can be thus stabilized to advantageously form a thick photoconductive layer in a direct-type radiation image detector (FPD) and in particular a vapor-deposited film of amorphous selenium serving as the photoconductive layer of the FPD.

The fitting portion 44 made of a heat insulating material can prevent heat from the heater 40 and the thermally expandable member 42 to be transmitted to the substrate S and also heat from the substrate S to be transmitted to the thermally expandable member 42. Prevention of heat transmission between the substrate S and the thermally expandable member 42 with the use of the fitting portion can facilitate control of the load to be applied to the substrate S as well as control of the temperature of the substrate S.

As in the embodiment under consideration, a plurality of temperature sensors of the contact detection mechanism are preferably disposed in the base, but this is not the sole case of the present invention. Only one temperature sensor may be provided, or a plurality of temperature sensors may be disposed not in a matrix but one-dimensionally.

By disposing a plurality of temperature sensors and measuring the substrate temperature at a plurality of points as in the embodiment under consideration, partial separation of the substrate from the substrate holder can also be detected to reliably bring the substrate into close contact with the substrate holder.

Measurement of the substrate temperature at such plurality of points offers more accurate substrate temperature values to enable detection of the state of contact of the substrate and temperature control for each area of the substrate.

It is preferable for the control unit to cause the actuators of the load applying mechanism disposed at the projections of the base to individually adjust the load to be applied to the substrate.

By adjusting the load in each actuator such that the load to be added is adjusted for each area of the substrate and in particular in each direction in which the base has a rectangular cross-sectional shape, the load to be applied to the substrate can be minimized to make the state of contact of the substrate with the substrate holder more uniform.

It is preferable that the vacuum evaporation apparatus 10 also have a thermally conductive sheet (heat conductive sheet) for uniformly transmitting heat to the substrate S which is provided under the lower surface of the temperature adjusting plate 50, that is, between the temperature adjusting plate 50 and the substrate holder 13. Provision of the thermally conductive sheet enables heat from the temperature adjusting plate 50 to be uniformly transmitted to the substrate holder with high efficiency.

The heating/cooling mechanism is provided within the temperature adjusting plate in the embodiment under consideration. However, this is not the sole case of the present invention, and the temperature adjusting plate may comprise a support plate for supporting the substrate holder and a heating/cooling mechanism disposed on an opposite side of the support plate from the surface at which the support plate comes in contact with the substrate holder. In this case, it is preferable to provide the above-mentioned thermally conductive sheet between the support plate and the heating/cooling mechanism as well.

In this embodiment, film deposition is made with the substrate fixed. However, the present invention is not limited to this and the substrate may be rotated or reciprocated when the evaporable material is deposited to form a film.

The vacuum film deposition apparatus of the present invention may include a means for transporting the substrate S (substrate holder 13) and vacuum evaporation apparatuses connected to each other such that a plurality of films can be formed on the single substrate S.

Even in the case of forming a multi-layered film on the substrate by vapor deposition as the substrate holder holding the substrate is moved, a proper load can be applied to the substrate in accordance with the conditions of the vacuum evaporation apparatus to form the multi-layered film thereon and the substrate and the substrate holder can be brought into close contact with each other in spite of changes in the substrate weight, whereby a uniform vapor-deposited film can be formed on the substrate. Irrespective of the type of the vacuum evaporation apparatus used, the state of contact between the substrate and the substrate holder can be detected under the same conditions.

It is preferable for the substrate holder also to have a guide along each of the end faces of the substrate where the load applying mechanism is not provided. The guide provided can prevent the substrate from shifting in the direction in which the base has a rectangular cross-sectional shape.

In this embodiment, the actuators of the load applying mechanism are provided on two end faces of the substrate. However, the present invention is not limited to this but may be configured such that the actuators are only provided on one end face side of the substrate with the other end face side of the substrate fixed. In other words, the substrate and the substrate holder can be brought into close contact with each other with an appropriate Toad by adjusting the load to be applied to one end face of the substrate alone with the actuators provided on this end face side while the other end face of the substrate is fixed. The substrate can be uniformly heated to form a uniform film on the substrate by vapor deposition.

In this embodiment, the actuators are provided on the opposed two end faces of the substrate. However, actuators may be provided at the four sides of the substrate such that the load to be applied to the four sides of the substrate may be adjusted with these actuators.

It is preferable to provide more than one actuator because this layout enables a more appropriate load to be applied to the substrate to adjust the state of contact between the substrate and the substrate holder more precisely as described above. However, this is not the sole case of the present invention and a single actuator may be used to adjust the load to be applied to one end face of the substrate. For example, the embodiment shown in FIG. 2 may be configured such that one actuator is provided on each end face of the substrate.

In the embodiment under consideration, the substrate supporting surface of the base has a concave shape, that is, a shape projecting toward the opposite surface side from the substrate supporting surface. However, this is not the sole case of the present invention and the substrate supporting surface of the base has a convex shape, that is, a shape projecting toward the surface side on which the substrate supporting surface contacts the substrate.

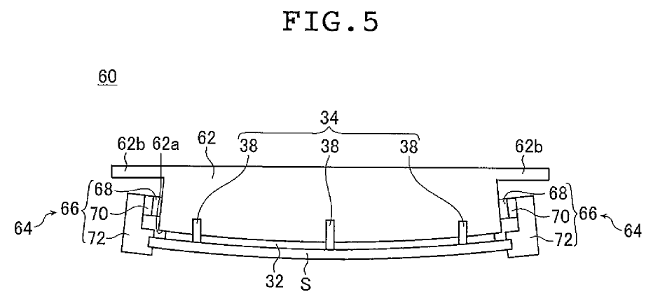

FIG. 5 is a front view schematically showing the structure of another embodiment of the substrate holder of the present invention.

Because a substrate holder 60 shown in FIG. 5 has an arrangement which, aside from a base 62 and a load applying mechanism 64, is the same as that of the substrate holder 13 shown in FIG. 2, like components are denoted by the same reference symbols as in the substrate holder 13 and repeated explanations of such components are omitted below. The following description focuses on the distinctive features of the substrate holder 60.

The substrate holder 60 includes the base 62 for holding the substrate S, a thermally conductive sheet 32, a contact detection mechanism 34 and the load applying mechanism 64. Although not shown in FIG. 5, the substrate holder 60 also includes a control unit and a holder communicating portion as in the substrate holder 13 shown in FIG. 1A, 1B and 2.

The base 62 is in the shape of a plate whose region where the base 62 contacts the substrate S (more precisely via the thermally conductive sheet 32) is convex when seen from the cross section in a predetermined direction (horizontal direction in FIG. 5), that is, a substrate supporting surface 62a is curved such that the distance between the substrate supporting surface 62a and its opposite surface increases from both ends toward the central portion. When seen in a direction perpendicular to the predetermined direction (direction perpendicular to the paper in FIG. 5), the base 62 has a rectangular cross-sectional shape.

The base 62 is provided on both ends of the surface opposite from the surface supporting surface 62a with projections 62b supported by hooks of support portions.

The load applying mechanism 64 includes a plurality of actuators 66.

The actuators 66 are provided on two surfaces between the substrate supporting surface 62a and the projections 62b (i.e., two lateral surfaces at both ends of the curved substrate supporting surface 62a). Although one actuator 66 is shown at each end of the substrate supporting surface 62a in FIG. 5, the actuators 66 are spaced apart from each other at predetermined intervals in the direction perpendicular to the paper in FIG. 5.

One actuator 66 has a heater 68, a thermally expandable member 70 and a fitting portion 72, which are stacked in this order on each lateral surface of the base 62.

The fitting portion 72 pinches one end of the substrate S from its upper and lower surfaces (i.e., the surface on which a film is to be vapor-deposited and its opposite surface) and supports it.

The load applying mechanism 64 supports the substrate S by causing the fitting portions 72 of the actuators 66 to apply an outward load to the substrate S (i.e., pull the substrate S) to bring the substrate S into close contact with the substrate supporting surface 62a.

In the load applying mechanism 64, the heaters 68 heat the thermally expandable members 70, which expand to move the fitting portions 72 outward, enabling the load in the pulling direction applied to the substrate S to be increased. The substrate S can be brought into close contact with the convex substrate supporting surface 62a by thus pulling the substrate S with a larger force. In the case where the substrate S has been separated from the substrate holder 60, the tensile load the load applying mechanism 68 applies to the substrate S can be more increased to bring the substrate S into close contact with the substrate supporting surface 62a of the base 62 of the substrate holder 60 (more precisely the thermally conductive sheet 32).

The substrate can be brought into close contact with the substrate holder by using the substrate supporting surface of the base in a convex shape and applying a tensile load to the substrate. By adjusting the load in the load applying mechanism, the substrate and the substrate holder can be brought into close contact with each other with an appropriate load to achieve formation of a uniform film by vapor deposition without causing deformation of the substrate.

While the substrate holder and the vacuum film deposition apparatus of the present invention have been described above in detail, the present invention is by no means limited to the foregoing embodiments and it should be understood that various improvements and modifications can of course be made without departing from the scope and spirit of the invention.

In the above-mentioned embodiments, temperature sensors are used in the contact detection mechanism to detect the state of contact between the substrate and the substrate holder based on changes in temperature, because they can also be used in adjusting the substrate temperature and enable reduction in the number of components of the apparatus. However, this is not the sole case of the present invention.

For example, displacement sensors may be provided on the base side in the same manner as the above-mentioned temperature sensors to detect positional displacements of the back surface of the substrate S. Alternatively, displacement sensors may be provided on the front side of the substrate S to see whether a displacement exceeding the vapor deposition rate at which a film is formed on the surface of the substrate occurs on the substrate surface.

In the case of displacement detection, the load to be applied may be adjusted in accordance with the distance between the substrate and the substrate supporting surface.

The state of contact between the substrate and the base may be detected by an electric sensor configured such that a predetermined amount of current flows when the substrate is in contact with the base, whereas no current flows when the substrate is separated from the base.

In the case of using detection devices other than the temperature sensors for the contact detection mechanism, it is preferable to provide, in addition to the detection devices, temperature sensors for detecting the substrate temperature in order to adjust heating of the substrate made by the temperature adjusting plate.

The actuator that may be used in the load applying mechanism is not limited to one composed of a heater and a thermally expandable member, and use may be made of actuators of various systems (e.g., pneumatic, electromagnetic and electrostatic systems) that can adjust the load to be added Exemplary actuators that may be used include one which expands or contracts an air cylinder used in response to changes in amount of air introduced, or one in which a comb electrode is used to move an electrode stepwise.

The substrate holders used in the above-mentioned embodiments are of a detachable type, but use may be made of a vacuum evaporation apparatus having a substrate holder fixed at a predetermined position.

These embodiments have been described with the vacuum evaporation apparatus taken as an example. However, the present invention is not limited to this but may be applied to various apparatuses for forming a film on a substrate, as exemplified by sputtering apparatuses, CVD apparatuses and various other vacuum film deposition apparatuses (apparatuses for use in film formation by vapor-phase deposition).

What is claimed is:

1. A vacuum film deposition apparatus in which a film is formed on a substrate by a vacuum film deposition process, comprising:
a holder which has a substrate supporting surface which is in a curved shape and is brought into contact with said substrate;
a contact detection mechanism which detects a state of contact between said substrate and said substrate supporting surface;
a load applying mechanism which is provided outside said substrate supporting surface of said holder and supports said substrate by applying a load to end faces of said substrate; and
a control unit which controls the load said load applying mechanism applies to said substrate based on output from said contact detection mechanism.

2. The vacuum film deposition apparatus according to claim 1, wherein said contact detection mechanism has detection devices disposed at a plurality of points of said substrate supporting surface in said holder, and said detection devices are used to detect the state of contact between said substrate and said substrate supporting surface of said holder at the plurality of points.

3. The vacuum film deposition apparatus according to claim 2, wherein said detection devices are displacement sensors which are provided at said substrate supporting surface of said holder contacting said substrate and detect a displacement of said substrate.

4. The vacuum film deposition apparatus according to claim 2, wherein said detection devices are temperature sensors which are provided at said substrate supporting surface of said holder contacting said substrate and detect a temperature of said substrate, said temperature sensors detecting the state of contact between said substrate and said substrate supporting surface of said holder based on changes in temperature.

5. The vacuum film deposition apparatus according to claim 1, wherein said control unit controls the load applied by said load applying mechanism to said substrate by changing stepwise the load to said substrate by a fixed amount.

6. The vacuum film deposition apparatus according to claim 1, wherein said holder has a thermally conductive sheet provided on said substrate supporting surface of said holder contacting said substrate.

7. The vacuum film deposition apparatus according to claim 1, wherein said load applying mechanism is provided outside both ends of said substrate supporting surface of said holder, supports said substrate by applying the load to the end faces of said substrate, and includes first actuators for applying a load to a first end face of said substrate and second actuators for applying a load to a second end face of said substrate which is opposite from said first end face.

8. The vacuum film deposition apparatus according to claim 1, further comprising a holder mounting mechanism which is used for attachment and detachment of said holder.

9. A substrate holder for holding a substrate on which a film is to be formed, comprising:
a base having a substrate supporting surface which is in a curved shape and is brought into contact with said substrate;
a contact detection mechanism which detects a state of contact between said substrate and said substrate supporting surface;
a load applying mechanism which is provided outside said substrate supporting surface of said base and supports said substrate by applying a load to end faces of said substrate; and
a control unit which controls the load said load applying mechanism applies to said substrate based on output from said contact detection mechanism.

10. The substrate holder according to claim 9, wherein said contact detection mechanism has detection devices disposed at a plurality of points of said substrate supporting surface, and said detection devices are used to detect the state of contact between said substrate and said substrate supporting surface at the plurality of points.

11. The substrate holder according to claim 10, wherein said detection devices are displacement sensors which are provided at said substrate supporting surface contacting said substrate and detect a displacement of said substrate.

12. The substrate holder according to claim 10, wherein said detection devices are temperature sensors which are provided at said substrate supporting surface contacting said substrate and detect a temperature of said substrate, said temperature sensors detecting the state of contact between said substrate and said substrate supporting surface based on changes in temperature.

13. The substrate holder according to claim 9, wherein said control unit controls the load applied by said load applying mechanism to said substrate by changing stepwise the load to said substrate by a fixed amount.

14. The substrate holder according to claim 9, wherein said holder has a thermally conductive sheet provided on said substrate supporting surface contacting said substrate.

15. The substrate holder according to claim 9, wherein said load applying mechanism is provided outside both ends of said substrate supporting surface, supports said substrate by applying the load to the end faces of said substrate, and includes first actuators for applying a load to a first end face of said substrate and second actuators for applying a load to a second end face of said substrate which is opposite from said first end face.
